(19) United States
(12) Patent Application Publication
(10) Pub. No.: US 2015/0155516 A1
(43) Pub. Date: Jun. 4, 2015

(54) ORGANIC LIGHT-EMITTING ELEMENT AND PRODUCTION METHOD THEREFOR

(71) Applicant: PANASONIC CORPORATION, Osaka (JP)

(72) Inventors: Saori Yamashita, Aichi (JP); Kaori Akamatsu, Osaka (JP)

(73) Assignee: PANASONIC CORPORATION, Osaka (JP)

(21) Appl. No.: 14/407,587

(22) PCT Filed: Jun. 20, 2013
(86) PCT No.: PCT/JP2013/003878

§ 371 Date: Dec. 12, 2014

(30) Foreign Application Priority Data
Jun. 20, 2012 (JP) 2012-138378

(51) Int. Cl. H01L 51/50; H01L 51/56; H01L 51/52

(52) U.S. Cl. CPC H01L 51/5012; H01L 51/5203; H01L 51/5088; H01L 51/56

(57) ABSTRACT

An organic light-emitting element having a substrate, an anode on the substrate, a bank layer on or above the substrate that has an opening above the anode, a hole transport layer in the opening that contains organic material, an organic light-emitting layer on the hole transport layer that contains organic light-emitting material, and a cathode above the organic light-emitting layer. A portion of the hole transport layer is located between a periphery of the organic light-emitting layer and a side surface of the bank layer facing the opening. Carrier mobility of the hole transport layer is 1.0×10⁻³(cm²/Vs) or less.

### TECHNICAL FIELD

The present invention is related to organic electroluminescent elements (hereafter, “organic light-emitting elements”) using electroluminescence of organic material, and methods for producing organic light-emitting elements.

### BACKGROUND ART

An organic light-emitting element is a current-driven type of light-emitting element that has an organic light-emitting layer containing organic light-emitting material that emits light when a voltage is applied thereto. The organic light-emitting layer is provided between an electrode pair composed of an anode and a cathode. Typically, the organic light-emitting element is produced by forming the electrodes, organic light-emitting layer, etc., in a specific order on a substrate. Various methods exists for forming each layer of the organic light-emitting element, depending on conditions such as material, desired thickness, etc. For example, there is a method of applying then drying a solution containing a material. Inkjet, flexographic printing, spin coating, etc., are example methods of applying the solution.

Among these methods, inkjet methods have advantages such as: thickness of a layer can be controlled in units of several microns; application amount of the material can be reduced to a minimal amount; ink containing material for each of three primary colors can be easily applied, making production of full-color display devices easy; etc. Thus, inkjet methods are attracting research and development, and attention as methods of producing organic light-emitting elements and organic light-emitting devices provided with organic light-emitting elements (Patent Literature 1).

### CITATION LIST

### Patent Literature

### [Patent Literature 1]

Japanese Patent Application Publication No. 2001-291584

### SUMMARY OF INVENTION

### Technical Problem

Further improvements in light-emission characteristics are being sought, because in recent years, organic light-emitting elements are being widely used as display devices, light sources, etc. On the other hand, from a perspective of energy conservation, suppression of power consumption of organic light-emitting elements is also being sought. In order to obtain an organic light-emitting element having good light-emitting properties and suppressing power consumption, luminance efficiency of the organic light-emitting element may be improved, for example. Here, “luminance efficiency” means luminance with respect to input power.

An aim of the present invention is to provide an organic light-emitting element having excellent light-emitting properties.

### Solution to Problem

To achieve the above aim, an organic light-emitting element pertaining to one aspect of the present invention comprises: a substrate; a first electrode on the substrate; a bank layer on or above the substrate, the bank layer having an opening above the first electrode; an organic functional layer in the opening, the organic functional layer containing organic material; an organic light-emitting layer on the organic functional layer, the organic light-emitting layer containing organic light-emitting material; and a second electrode above the organic light-emitting layer, wherein a portion of the organic functional layer is located between at least a portion of a periphery of the organic light-emitting layer and a side surface of the bank layer facing the opening, and carrier mobility of the organic functional layer is 1.0×10⁻³ cm²/Vs or less.

### Advantageous Effects of Invention

Because the organic light-emitting element pertaining to one aspect of the present invention has a configuration in which a portion of the organic functional layer is located between at least a portion of a periphery of the organic light-emitting layer and a side surface of the bank layer facing the opening, not-wetted areas of the organic light-emitting layer are suppressed. Not-wetted areas are a cause of degradation in luminance efficiency of the organic light-emitting element. Note that here, “not-wetted areas of the organic light-emitting layer” means that, when the organic light-emitting layer is being formed, ink containing material of the organic light-emitting layer does not spread to cover all of the opening of the bank layer, leading to regions in the opening in which the organic light-emitting layer is not formed. Further, carrier mobility of the organic functional layer is 1.0×10⁻³ (cm²/Vs). Thus, leak current is unlikely to flow between the organic functional layer and the second electrode. As a result, degradation in luminance efficiency of the organic light-emitting element is suppressed. Accordingly, the organic light-emitting element having good light-emitting properties is obtained.

### BRIEF DESCRIPTION OF DRAWINGS

FIG. 1A is a cross-section diagram illustrating an organic light-emitting display device including an organic light-emitting element pertaining to an embodiment, and FIG. 1B is an enlargement of FIG. 1A.

FIG. 2 is a plan view diagram illustrating a layout of a bank layer and an organic light-emitting layer in the organic light-emitting display device illustrated in FIG. 1.

FIGS. 3A, 3B, and 3C are process diagrams illustrating a method of producing the organic light-emitting display device illustrated in FIG. 1: FIG. 3A illustrates a substrate on which an anode is provided; FIG. 3B illustrates a process of forming an ITO layer and a hole injection layer; and FIG. 3C illustrates a process of forming a bank layer.

FIGS. 4A, 4B, and 4C are process diagrams illustrating the method of producing the organic light-emitting display device illustrated in FIG. 1: FIG. 4A illustrates a process of applying ink to an opening in the bank layer; FIG. 4B illustrates a process of forming a hole injection layer; and FIG. 3C illustrates a process of applying ink on the hole injection layer.

FIGS. 5A and 5B, are process diagrams illustrating the method of producing the organic light-emitting display device illustrated in FIG. 1: FIG. 5A illustrates a process of forming the organic light-emitting layer; and FIG. 5B illustrates a process of forming an electron injection layer, a cathode, and a sealing layer.

FIGS. 6A and 6B are illustrations of organic light-emitting elements in which shapes of hole transport layers are different: FIG. 6A illustrates a comparative example; and FIG. 6B illustrates the organic light-emitting display device illustrated in FIG. 1.

FIG. 7 is a cross-section diagram of an organic light-emitting element used in simulations.

FIGS. 8A and 8B are enlargements of an area near the bank layer of the organic light-emitting element used in the simulations: FIG. 8A illustrates an organic light-emitting layer of thickness 80 nm; and FIG. 8B illustrates an organic light-emitting layer of thickness 50 nm.

FIGS. 9A and 9B are enlargements of an area near the bank layer of an organic light-emitting element used in the simulations: FIG. 8A illustrates an organic light-emitting layer of thickness 80 nm; and FIG. 8B illustrates an organic light-emitting layer of thickness 50 nm.

FIG. 10 is a diagram illustrating how carrier mobility of the organic functional layer affects luminance efficiency.

FIG. 11 is a diagram illustrating how carrier mobility of the organic light-emitting layer affects luminance efficiency.

FIG. 12 is a diagram illustrating how HOMO difference between the organic functional layer and the organic light-emitting layer affects luminance efficiency.

FIG. 13 is a diagram illustrating correlation between HOMO difference between the organic functional layer and the organic light-emitting layer and carrier mobility of the organic light-emitting layer, with respect to luminance efficiency.

### DESCRIPTION OF EMBODIMENT

[Developments that LED to One Aspect of the Present Invention]

Prior to describing one aspect of the present invention in detail, the following is a description of developments that led to the one aspect of the present invention.

Further improvements in light-emission characteristics are being sought, because in recent years, organic light-emitting devices are being widely used as display devices, light sources, etc. An organic light-emitting element may include: a substrate on which there is a first electrode; a bank layer above the substrate, having an opening; an organic functional layer and an organic light-emitting layer in the opening; and a second electrode on the organic light-emitting layer. In production of such an organic light-emitting element, as a method of forming the organic functional layer or another layer in the opening, a solution containing material may be applied using an inkjet method and subsequently dried, for example. However, in an organic light-emitting element produced using an inkjet method, not-wetted areas of the organic light-emitting layer may occur in the opening in the bank layer. Not-wetted areas of the organic light-emitting layer occur when ink containing organic light-emitting material is applied to the opening, but due to liquid repellency of the bank layer, viscosity of the applied ink, etc., ink does not spread over a portion of the opening. In a not-wetted area of the organic light-emitting layer, a leak path occurs between the organic functional layer and the second electrode because the organic functional layer and the second electrode are in contact with each other. As a result, in an organic light-emitting element having a not-wetted area of an organic light-emitting layer, luminance efficiency decreases and light-emitting properties degrade.

The inventors found that in an organic light-emitting element having a structure as described below, not-wetted areas of the organic light-emitting layer could be suppressed. Specifically, the organic light-emitting element has the organic functional layer present between at least a portion of a periphery of the organic light-emitting layer and a side surface of the bank layer facing the opening.

However, in such a structure, because at least a portion of an upper surface of the organic functional layer and the second electrode (or in some situations an intermediate layer between the organic light-emitting layer and the second electrode) are in contact with each other, a leak path may occur between the organic functional layer and the second electrode. When leak current flows along a leak path between the organic functional layer and the second electrode, application of voltage to the organic light-emitting layer is impeded, causing reduction in luminance efficiency. In response to this problem, the inventors defined carrier mobility of the organic functional layer. As a result, even in an organic light-emitting element in which not-wetted areas of the organic light-emitting layer are suppressed, leak current can be suppressed. Accordingly, an organic light-emitting element having good light-emitting properties was implemented. The aspect of the present invention was derived from such developments.

### [Overview of One Aspect of the Present Invention]

An organic light-emitting element pertaining to one aspect of the present invention comprises: a substrate; a first electrode on the substrate; a bank layer on or above the substrate, the bank layer having an opening above the first electrode; an organic functional layer in the opening, the organic functional layer containing organic material; an organic light-emitting layer on the organic functional layer, the organic light-emitting layer containing organic light-emitting material; and a second electrode above the organic light-emitting layer, wherein a portion of the organic functional layer is located between at least a portion of a periphery of the organic light-emitting layer and a side surface of the bank layer facing the opening, and carrier mobility of the organic functional layer is 1.0×10⁻³ cm²/Vs or less.

Thus, the organic light-emitting element having excellent light-emitting properties is provided.

Further, an organic light-emitting element pertaining to one aspect of the present invention may be the organic light-emitting element wherein a difference between HOMO of the organic functional layer and HOMO of the organic light-emitting layer is 0.28 eV or less, carrier mobility of the mobility of the organic light-emitting layer is 6.3×10⁻⁸ cm²/Vs or greater,

Y≦0.0103Ln(X)+0.2109(1.0×10⁻⁴≦X≦1.0×10⁻⁴) Math 1

Y≦0.0571Ln(X)+0.6208(1.0×10⁻⁴≦X≦1.0×10⁻⁴) Math 2

where X is the carrier mobility of the organic light-emitting layer and Y is the difference between HOMO of the organic functional layer and HOMO of the organic light-emitting layer.

Further, an organic light-emitting element pertaining to one aspect of the present invention may be the organic light-emitting element wherein the side surface of the bank layer facing the opening is inclined with respect to a surface of the substrate, periphery of the organic functional layer is located on the side surface of the bank layer facing the opening, and the periphery of the organic light-emitting layer is positioned further towards a center of the opening than the periphery of the organic functional layer.

Further, an organic light-emitting element pertaining to one aspect of the present invention may be the organic light-emitting element further comprising: an intermediate layer between the organic light-emitting layer and the second electrode.

Further, an organic light-emitting element pertaining to one aspect of the present invention may be the organic light-emitting element further comprising: a carrier injection layer between the first electrode and the organic functional layer. Further, an organic light-emitting element pertaining to one aspect of the present invention may be the organic light-emitting element wherein the carrier injection layer is at least covered by the organic functional layer.

Further, an organic light-emitting element pertaining to one aspect of the present invention may be the organic light-emitting element wherein the carrier injection layer is located in regions other than between the first electrode and the organic functional layer, and the portion of the carrier injection layer in the regions other than between the first electrode and the organic functional layer is located between the substrate and the bank layer.

Further, an organic light-emitting element pertaining to one aspect of the present invention may be the organic light-emitting element further comprising: metal auxiliary wiring on the substrate, wherein the second electrode and the auxiliary wiring are connected.

A method of producing an organic light-emitting element pertaining to the present invention comprises: preparing a substrate having a plurality of first electrodes thereon; forming a bank layer on or above the substrate, the bank layer having openings, each opening being above a respective one of the first electrodes; forming organic functional layers in the openings by applying then drying a solution containing organic material, carrier mobility of the organic functional layers being 1.0×10⁻³ cm²/Vs or less; forming organic light-emitting layers on the organic functional layers by applying then drying a solution containing organic light-emitting material; and forming a second electrode above the organic light-emitting layers, wherein a portion of each organic functional layer is located between at least a portion of a periphery of a respective one of the organic light-emitting layers and a corresponding side surface of the bank layer facing a respective one of the openings.

Thus, the method of producing an organic light-emitting element having excellent light-emitting properties is provided.

### EMBODIMENT

### Embodiment 1

### 1. Structure

### (Organic Light-Emitting Display Device 10)

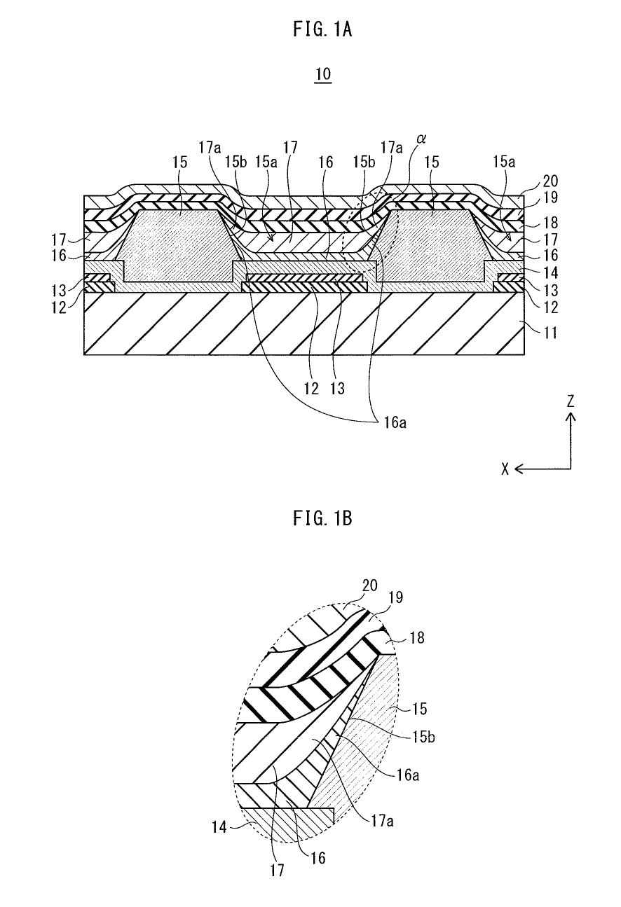

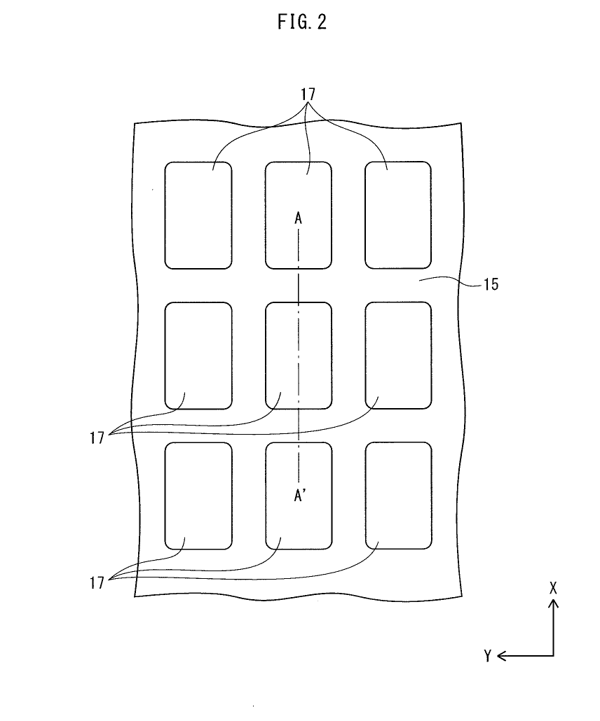

The following is a detailed description, with reference to the drawings, of an embodiment of the present invention. FIGS. 1A and 1B are schematic cross-section diagrams illustrating a structure of an organic light-emitting display device 10 including an organic light-emitting element pertaining to the present embodiment. FIG. 2 is a plan view diagram illustrating a layout of a bank layer and an organic light-emitting layer in the organic light-emitting display device 10 illustrated in FIG. 1A and FIG. 1B. FIG. 1A corresponds to a cross-section diagram along A-A′ in FIG. 2. Note that the organic light-emitting display device 10 is a top-emission type in which light from the organic light-emitting layer is reflected at an opposite side of a glass substrate. Further, the organic light-emitting display device 10 is, for example, an application type in which the organic functional layer and the organic light-emitting layer are produced by application by an inkjet method. Note that a DC power source is connected to the anode and the cathode, and power is supplied to the organic light-emitting element from outside.

As illustrated in FIG. 1A, the organic light-emitting display device 10 has, on one main surface of a substrate 11, an anode 12 as a first electrode, an ITO layer 13, a hole injection layer 14, a bank layer 15, a hole transport layer 16 as an organic functional layer, an organic light-emitting layer 17, an electron injection layer 18, a cathode 19 as a second electrode, and a sealing layer 20, layered in the stated order. The organic light-emitting layer 17 is formed in an opening 15a in the bank layer 15. Further, as described above, the anode 12 and the cathode 19 are electrically connected to a DC power source.

As illustrated in FIG. 2, a plan view shape of the organic light-emitting layer 17 is a rectangular shape with rounded corners and a long side. However, the present invention is not limited in this way. The plan view shape of the organic light-emitting layer 17 may be elliptic, circular, hexagonal, etc. Note that a location where the organic light-emitting layer 17 is formed corresponds to the opening 15a in the bank layer 15. The following is a detailed description of each layer in the organic light-emitting display device 10.

### (Substrate 11, Anode 12, ITO Layer 13)

Returning to FIGS. 1A and 1B, the substrate 11 is a base material of the organic light-emitting display device 10 and is composed of alkali-free glass, for example. However, the substrate 11 is not limited in this way, and may be formed from soda glass, non-fluorescent glass, phosphate glass, borate glass, silica glass, acrylic resin, styrene resin, polycarbonate resin, epoxy resin, polyethylene, polyester, silicon resin, or insulating material such as alumina.

Although not illustrated, a thin-film transistor (TFT) for driving the organic light-emitting display device is formed on a surface of the substrate 11, and the anode 12 is formed above TFT. The anode 12 is composed, for example, of a silver, palladium, and copper (APC) alloy. However, the anode 12 is not limited in this way, and may be formed from an aluminium, cobalt, and lanthanum (ACL) alloy, a silver, rubidium, and gold (ARA) alloy, a molybdenum and chromium (MoCr) alloy, a nickel and chromium (NiCr) alloy, etc.

The indium tin oxide (ITO) layer 13 is interposed between the anode 12 and the hole injection layer 14 and has a function of improving bonding between each layer. note that it is possible to omit the ITO layer 13 depending on material of the anode 12.

### (Hole Injection Layer 14)

The hole injection layer 14 is formed covering the substrate 11 on which the ITO layer 13 is formed. Further, while covering all of the anode 12 and the ITO layer 13, the hole injection layer 14 is covered by the bank layer 15 and the hole transport layer 16. The hole injection layer 14 aids hole stabilization, aids hole generation, and has a function of injecting holes with respect to the organic light-emitting layer 17. The hole injection layer 14 is composed of tungsten oxide, for example. However, the hole injection layer 14 is not limited in this way, and may be formed from oxides of silver (Ag), molybdenum (Mo), chromium (Cr), vanadium (V), nickel (Ni), iridium (Ir), etc., or may be formed from a conductive polymeric material such as a polymer mixture of poly(3,4-ethylenedioxythiophene) and polystyrene sulfonic acid (PEDOT). However, when using an application material such as PEDOT, the hole injection layer 14 is not formed covering the substrate 11 and is instead formed in the opening 15a of the bank layer 15.

### (Bank Layer 15)

The bank layer 15 is provided with the opening 15a above the anode 12. Further, the opening 15a is surrounded by an inclined surface 15b that is a side surface of the bank layer 15. The hole transport layer 16 and the organic light-emitting layer 17 are formed in the opening 15a. In the cross-section in FIG. 1A, the bank layer 15 appears to have two tapered banks, but in plan view the bank layer 15 is a layer as illustrated in FIG. 2. The bank layer 15 is composed of a photosensitive resist material, for example acrylic resin. However, the bank layer 15 is not limited in this way, and may be formed from an insulating organic material such as polyimide resin, Novalac-type phenolic resin, etc.

### (Hole Transport Layer 16)

The hole transport layer 16 has a concave shape and is formed in the opening 15a. Further, a periphery 16a of the hole transport layer 16 runs up the inclined surface 15b of the bank layer 15 that faces the opening 15a. Note that the “periphery 16a of the hole transport layer 16” refers to a portion from an end of a flat portion of the hole transport layer 16 to a highest surface of an upwards-standing portion of the hole transport layer 16. The hole transport layer 16 is composed of poly(vinylcarbazole) (PVK), for example. However, the hole transport layer 16 is not limited in this way, and as long as the hole transport layer 16 contains organic material the hole transport layer 16 may be formed from a material that can form a thin film by being dissolved in a solvent and applied to a substrate, including for example, polyfluorene, polyphenylene vinylene, and pendant-type, dendrimer-type, and coating-type low molecular weight materials. Note that the hole transport layer 16 has carrier mobility of 1.0×10⁻³(cm²/Vs) or less.

### (Organic Light-Emitting Layer 17)

The organic light-emitting layer 17 is formed on the hole transport layer 16. The hole transport layer 16 is present everywhere between the periphery 17a of the organic light-emitting layer 17 and the inclined surface 15b of the bank layer 15, and the periphery 17a of the organic light-emitting 17 is in contact with the hole transport layer 16. Further, the periphery 17a of the organic light-emitting layer 17 is positioned further inside the opening 15a than the periphery 16a of the hole transport layer 16. Here, “the periphery 17a of the organic light-emitting layer 17” is a portion of the organic light-emitting layer 17 that is formed on the periphery 16a of the hole transport layer 16. In this way, an advantageous effect of the present invention is achieved, details of which are described later. The organic light-emitting layer is composed of poly(9,9-di-n-octylfluorene-alt-benzothiadiazole) (F8BT), which is an organic polymer. However, the organic light-emitting layer 17 is not limited in this way, and as long as the organic light-emitting layer 17 includes organic light-emitting material, fluorescent material may be used such as, for example, an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, anthracene compound, cyanine compound, acridine compound, metal complex of an 8-hydroxyquinoline compound, metal complex of a 2-bipyridine compound, complex of a Schiff base and a group three metal, metal complex of oxine, rare earth metal complex, etc. Note that physical properties of the organic light-emitting layer 17 are described later.

### (Electron Injection Layer 18, Cathode 19, and Sealing Layer 20)

The electron injection layer 18 is formed covering the light-emitting layer 17 and an upper surface of the bank layer 15. The electron injection layer 18 is composed of sodium fluoride (NaF), for example. However, the electron injection layer 18 is not limited in this way, and may be formed from CaF₂, MgF₂, etc. Note that the electron injection layer 18 may be omitted in cases in which electron injection from the cathode 19 to the light-emitting layer 17 is sufficiently achieved.

The cathode 19 is formed above the organic light-emitting layer 17 via the electron injection layer 18. The cathode 19 is composed of ITO, for example. However, the cathode 19 is not limited in this way, and may be formed from indium zinc oxide (IZO), etc. In a case in which the cathode 19 is formed from aluminium (Al), etc., the cathode 19 is required to have a small thickness and to have light-transmissive properties.

The sealing layer 20 is formed on the cathode 19. The sealing layer 20 is composed of a material having gas barrier properties such as silicon nitride (SiN).

### 2. Method of Producing Organic Light-Emitting Display Device

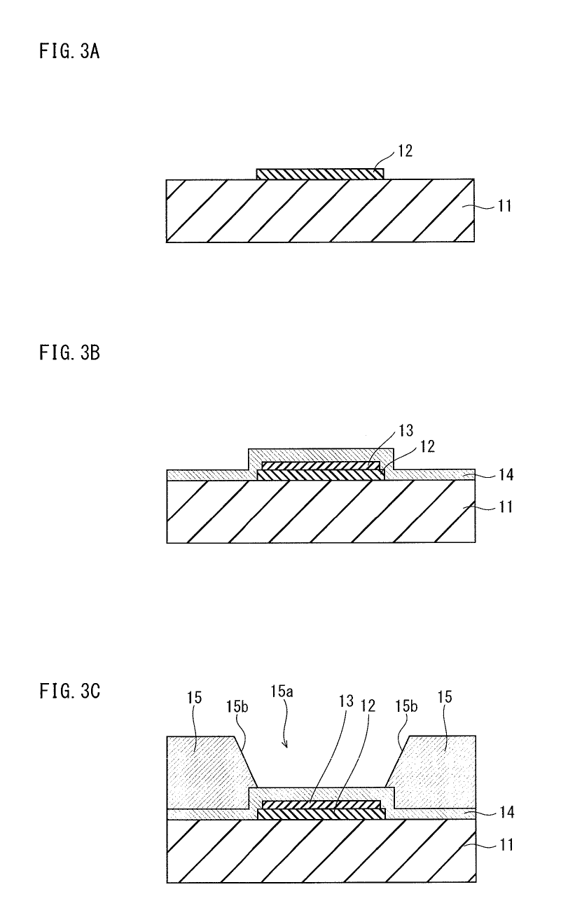

FIGS. 3A through 5B are process diagrams illustrating a method of producing the organic light-emitting display device 10 pertaining to the present embodiment.

First, as illustrated in FIG. 3A, the substrate 11 is formed having the anode 12 thereon. Specifically, the substrate 11 is placed in a deposition container of a sputtering film-forming apparatus. Next, a predefined sputtering gas is introduced into the deposition container, and the anode 12 is formed by reactive sputtering.

As illustrated in FIG. 3B, the ITO layer 13 is formed on the anode 12, and the hole injection layer 14 is formed covering the ITO layer 13. Specifically, first, the ITO layer 13 is formed on the anode 12 by sputtering in the deposition container. Next, a metal film is formed on a surface of the ITO layer 13 and a surface of the substrate 11 by sputtering. Subsequently, the hole injection layer 14 is formed by oxidizing the metal film.

Next, as illustrated in FIG. 3C, the bank layer 15 is formed having the opening 15a therein. Here, as described above, photosensitive resist material may be used as material of the bank layer 15. Specifically, first, material of the bank layer 15 is applied on the hole injection layer 14. Subsequently, after pre-baking, a mask is overlaid on the bank layer 15. The mask has a pattern for forming the opening 15a. To continue, after exposure to light from above the mask, unhardened, excess material of the bank layer 15 is washed out using developer. Subsequently, the bank layer 15 is formed by cleaning using pure water.

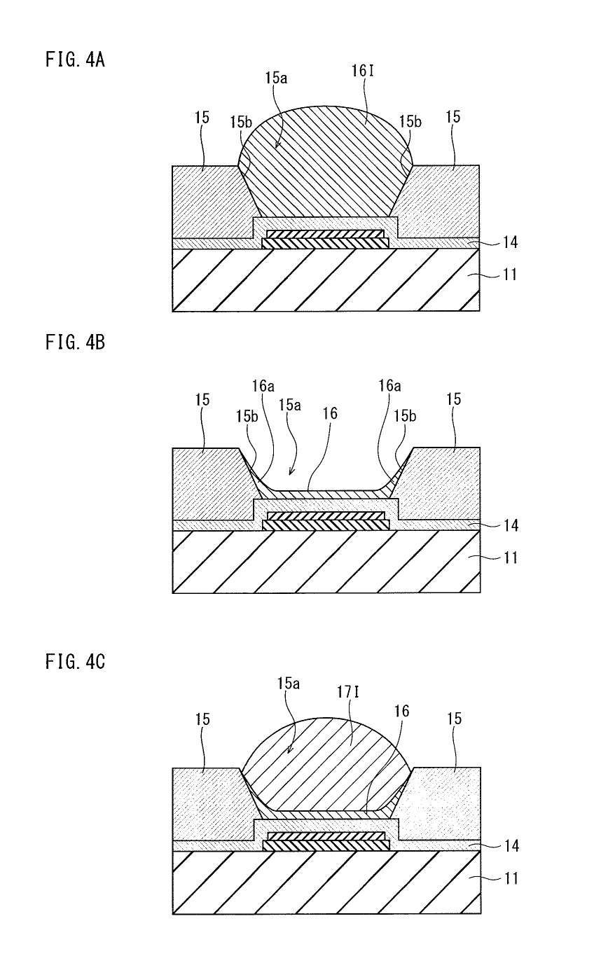

Further, as illustrated in FIG. 4A, ink 16I containing material of the hole transport layer 16 is applied in the opening 15A. Specifically, the ink 16I is applied in the opening 15A by using an inkjet method. The ink 16I is, for example, ink having a low density in which PVK is dissolved in a solvent at 0.4 wt/vol %. Note that here, “ink having a low density” is ink having a density of 3 wt/vol % or less. By using the ink 16I having low density, an amount of the ink 16I applied is greater than an amount of ink applied when using ink having standard density. Thus, when the ink 16I is applied, the ink 16I forms a shape swelling above the opening 15a. This stage of the method of production is described in detail later.

Subsequently, the hole transport layer 16 is formed having a concave shape, as illustrated in FIG. 4B, by drying the ink 16I. Specifically, immediately after applying the ink 16I, the ink 16I is quickly dried using a drying oven, thereby obtaining the hole transport layer 16 having a concave shape that has a pinning position at the same height as a highest surface of the bank layer 15.

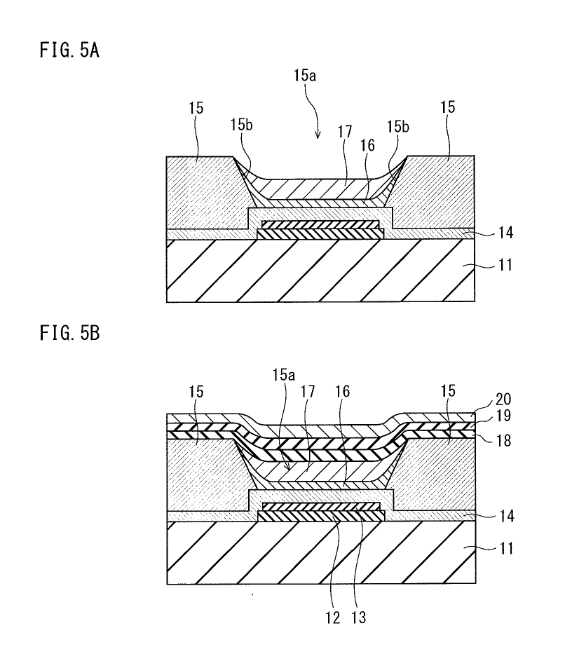

Further, as illustrated in FIG. 4C and FIG. 5A, ink 17I containing a material of the organic light-emitting layer 17 is applied in the opening 15a, and subsequently the organic light-emitting layer 17 is formed by drying the ink 17I. Specifically, the ink 17I is applied by using an inkjet method, then dried. Density of the ink 17I may be freely selected within a range that allows formation of the organic light-emitting layer 17, according to a desired thickness of the organic light-emitting layer 17. The ink 17I may be dried quickly immediately after application, or may be dried by a drying oven after a period of drying naturally.

Finally, as illustrated in FIG. 5B, the electron injection layer 18 including NaF, the cathode 19 including Al, and the sealing layer 20 are formed in the stated order above the organic light-emitting layer 17. Because low-melting-point metals such as Na and Al are used, the electron injection layer 18 and the cathode 19 may be formed by sputtering or vacuum deposition. The sealing layer 20 may be formed by sputtering, vacuum deposition, application, etc.

The organic light-emitting display device 10 is completed by the above processes.

### 3. Effects

The following describes structures and effects for achieving a solution to the technical problem. In the organic light-emitting element pertaining to the present embodiment: (3-1) suppression of not-wetted areas of the organic light-emitting layer is achieved by forming the hole transport layer having a concave shape in the opening; and (3-2) suppression of leak current is achieved by physical properties of the hole transport layer satisfying a condition 1. Further, (3-3) leak current is further suppressed by physical properties of the hole transport layer and the organic light-emitting layer satisfying conditions 2-4.

3-1. Suppression of not-Wetted Areas of the Organic Light-Emitting Layer

The following describes (3-1) suppression of not-wetted areas of the organic light-emitting layer by forming the hole transport layer having a concave shape in the opening.

### (Overview)

The inventors found that when an organic light-emitting layer is formed using an inkjet method on an organic functional layer such as a hole transport layer, a shape of the organic light-emitting layer is easily affected by a shape of an underlying base. Further, when an underlying base is sufficiently spread within an opening provided in a bank layer, not-wetted areas are less likely to occur in an organic light-emitting layer formed on the underlying base. Based on these findings, by forming the organic functional layer having a concave shape in the opening and forming the organic light-emitting layer on the organic functional layer, suppression of not-wetted areas of the organic light-emitting layer is achieved.

### (Shape of Organic Functional Layer and Organic Light-Emitting Layer)

First, in an organic light-emitting element produced using an inkjet method, shapes of the organic functional layer and the organic light-emitting layer are considered below. Typically, in an organic light-emitting element, not-wetted areas of the organic light-emitting layer may occur, but not-wetted areas of the organic functional layer do not occur. This difference occurs because of different inks used when producing the organic light-emitting layer and the organic functional layer.

The following considers ink containing material for the organic light-emitting layer and the organic functional layer. For example, in a top-emission-type of organic light-emitting element, thickness of a layer formed below the organic light-emitting layer is often smaller than thickness of the organic light-emitting layer. Specifically, an organic light-emitting element may be considered in which thickness of the organic functional layer is 10 nm and thickness of the organic light-emitting layer is 80 nm. When using an inkjet method, control of thickness of each layer is implemented through control of ink density. Specifically, it is necessary that density of ink used for forming the organic light-emitting layer of thickness 80 nm be higher than density of ink used for forming the organic functional layer of thickness 10 nm.

Here, not-wetted areas of each layer occur more easily as viscosity and surface tension of ink used in production of a layer increases. Ink having low density has lower viscosity and surface tension than ink having high density. Thus, a layer composed of ink having low density tends to spread across the opening more easily than a layer composed of ink having high density.

Thus, suppression of not-wetted areas is achieved in the organic functional layer composed of ink having a low density.

As described above, when an underlying base is sufficiently spread within an opening provided in a bank layer, because not-wetted areas are less likely to occur in an organic light-emitting layer formed on the underlying base, suppression of not-wetted areas of the organic light-emitting layer is achieved.

### (Method of Forming Organic Functional Layer)

The following describes a method of forming the hole transport layer having a concave shape. In order to form the hole transport layer having a concave shape, as described under “2. Method of producing organic light-emitting display device”, ink containing material for the hole transport layer has a low density and the ink is dried quickly immediately after application.

First, a reason for using ink having a low density is described below. When using ink having a lower density than is typical, in order to form the organic functional layer having a desired thickness, a greater amount of ink than is typical needs to be applied. Thus, ink having a low density is applied in greater quantity than when using ink having a high density, to an extent that the ink having a low density swells above the opening provided in the bank layer.

Next, a reason for quickly drying ink after application is described below. When ink is quickly dried after application, evaporation of solvent immediately starts in a state in which the ink has a density substantially the same as prior to application, and after the solvent completely evaporates, the hole transport layer is formed. In this way, a pinning position of the hole transport layer is high. On the other hand, when ink is slowly dried, density of the ink gradually increases during the drying period, after which the solvent completely evaporates and the hole transport layer is formed. In this way, a pinning position of the hole transport layer is low. In order to quickly dry ink after application, the ink may be immediately dried by a drying oven, for example.

In this way, the hole transport layer having a concave shape is formed by using an ink having a low density and containing material of the hole transport layer, and by quickly drying the ink after application.

### (Structure and Effects)

The following describes specific examples of suppression of not-wetted areas of the organic light-emitting layer in the organic light-emitting element. Note that in the specific examples, the organic functional layer is the hole transport layer.

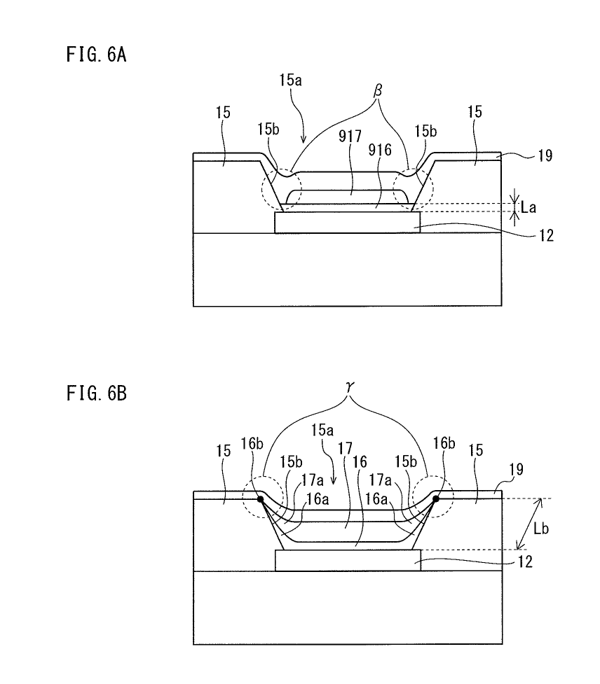

FIGS. 6A and 6B are illustrations of organic light-emitting elements in which shapes of the hole transport layers are different. FIG. 6A is a cross-section illustrating an organic light-emitting element pertaining to a comparative example and FIG. 6B is a cross-section illustrating the organic light-emitting element pertaining to the present embodiment. In both the comparative example and the present embodiment, density of the ink containing material for the hole transport layer is lower than density of the ink containing material for the organic light-emitting layer. Further, in both the comparative example and the present embodiment, density of the ink and method of drying the ink containing material for the organic light-emitting layer is the same.

In the comparative example, after applying the ink containing material for a hole transport layer 916, the ink is naturally dried, and finally dried in a drying oven to obtain the hole transport layer 916. Thus, as illustrated in FIG. 6A, the hole transport layer 916 has a flat shape. As a result, even if ink containing organic material for an organic light-emitting layer 917 is applied, the ink does not easily spread across the inclined surface 15b of the bank layer 15, which has a high liquid repellency, and suppression of not-wetted areas of the organic light-emitting layer 917 does not occur. When the cathode 19 is formed at areas where the organic light-emitting layer 917 is not formed, the hole transport layer 916 and the cathode 19 are in direct contact at an area β, which is indicated by and surrounded by a broken line in FIG. 6A. In this way, leak current flows from the anode 12 to the hole transport layer 916 and the cathode 19 at the area β. A distance La of a leak path along which leak current flows is the thickness of the organic functional layer 916.

On the other hand, as illustrated in FIG. 6B, in the present embodiment, the periphery 16a of the hole transport layer 16 covers all of the inclined surface 15b of the bank layer 15 so that the hole transport layer 16 has a concave shape. Thus, when ink containing material for the organic light-emitting layer 17 is applied using an inkjet method, the ink spreads easily, covering the periphery 16a of the hole transport layer 16, which has a low liquid repellency. This is because, as described above, when the organic light-emitting layer is formed on an organic functional layer such as the hole transport layer using an inkjet method, the organic light-emitting layer on a base layer is easily affected by the shape of the base layer. As a result, in the organic light-emitting display device, the hole transport layer 16 is present between the periphery 17a of the organic light-emitting layer 17 and the inclined surface 15b of the bank layer 15, and the periphery 17a of the organic light-emitting 17 is in contact with the hole transport layer 16. Thus, suppression of not-wetted areas of the organic light-emitting layer 17 is achieved, and the organic light-emitting element having excellent light-emitting properties is provided. In the same drawing, a pinning position 16b of the hole transport layer 16 matches the highest point of the inclined surface 15b of the bank 15. However, the hole transport layer 16 need not cover all of the inclined surface 15b of the bank layer 15. As long as the pinning position 16b of the hole transport layer 16 is at a position having the same height as a highest surface of the organic light-emitting layer 17, not-wetted areas of the organic light-emitting layer 17 are suppressed. Note that even in such a case, the hole transport layer 16 and the cathode 19 are in direct contact in an area γ surrounded by broken lines in FIG. 6B. Thus, leak current flows from the anode 12 to the cathode 19, creeping up the periphery 16a of the hole transport layer 16. A distance Lb of a leak path along which leak current flows is greater than the distance La. Thus, compared to the comparative example, leak current is suppressed in the present invention.

Further, in the organic light-emitting display device 10, the hole injection layer 14 is present in areas other than between the anode 12 and the hole transport layer 16. A portion of the hole injection layer in areas other than between the anode 12 and the hole transport layer 16 is present between the substrate 11 and the bank layer 15. Thus, the hole injection layer 14 does not become a leak path because the hole injection layer 14 does not cover the inclined surface 15b of the bank layer 15. Accordingly, carrier mobility of the hole injection layer 14 can be high, and luminance efficiency of the organic light-emitting layer 10 can be increased.

### 3-2. Selection of Physical Properties of Organic Functional Layer

### (Overview)

The following is a description of a solution to the problem of reduction of luminance efficiency due to leak current flowing along the leak path between the organic functional layer and the cathode in the organic light-emitting element described under (3-1). The inventors found that carrier mobility of the organic functional layer of 1.0×10⁻³(cm²/Vs) or less is sufficient to suppress reduction of luminance efficiency due to the leak path between the organic functional layer and the cathode. This became clear through simulations of changes in luminance efficiency when changing carrier mobility of the organic functional layer. The following describes in detail the simulation and four conditions thereof.

### (Simulation)

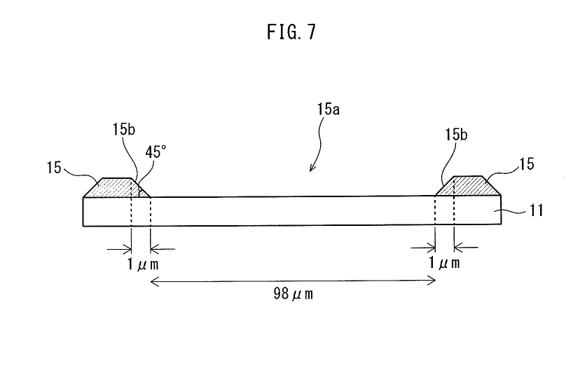

FIG. 7 is a cross-section diagram of an organic light-emitting element used in the simulation. The bank layer 15 having the opening 15a therein is on the substrate 11. A width of a bottom of the opening 15a was 98 μm. An incline angle of the inclined surface 15b of the bank layer 15 with respect to the substrate 11 was 45°, and a width of a bottom corresponding to the inclined surface 15b of the bank layer 15 was 1 μm. Simulation was performed assuming two different combinations, one in which thickness of the organic functional layer was 10 nm and thickness of the organic light-emitting layer was 50 nm, and another in which thickness of the organic functional layer was 10 nm and thickness of the organic light-emitting layer was 80 nm. The following is a more detailed description.

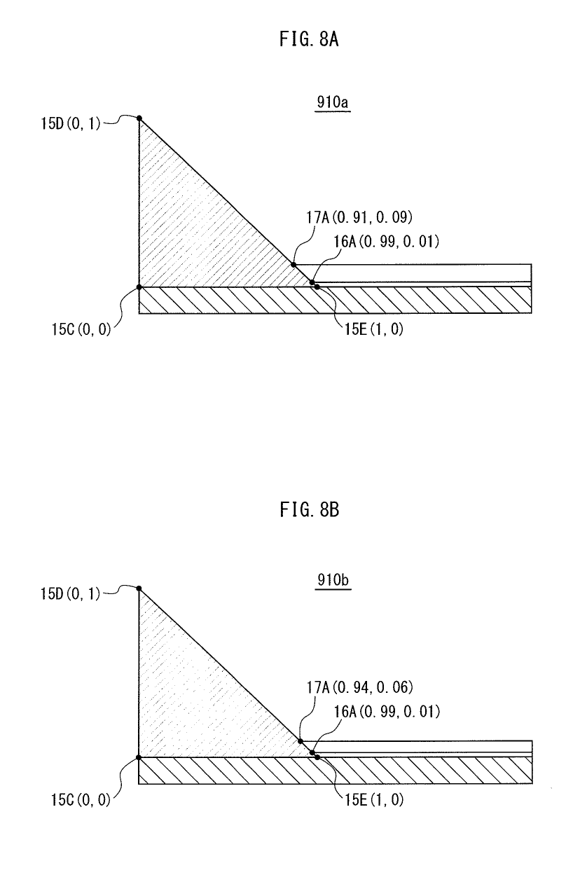

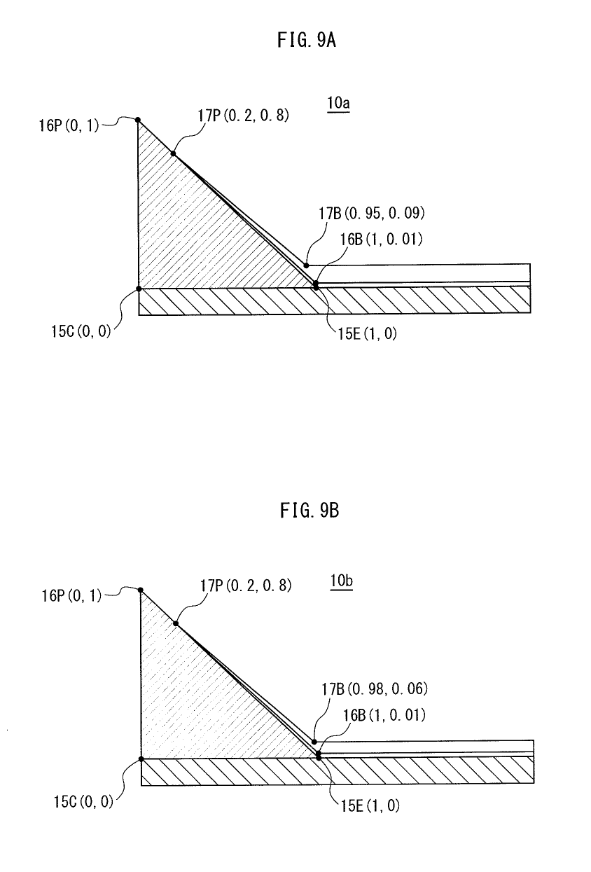

FIGS. 8A and 8B are enlargements of an area near the bank layer in organic light-emitting elements 910a and 910b used in the simulations, which include an organic functional layer having a flat shape. FIG. 8A corresponds to the case in which thickness of the organic functional layer was 10 nm and thickness of the organic light-emitting layer was 80 nm. FIG. 8B corresponds to the case in which thickness of the organic functional layer was 10 nm and thickness of the organic light-emitting layer was 50 nm. FIGS. 9A and 9B are enlargements of an area near the bank layer in organic light-emitting elements 10a and 10b used in the simulations, which include an organic functional layer having a concave shape. FIG. 9A corresponds to the case in which thickness of the organic functional layer was 10 nm and thickness of the organic light-emitting layer was 80 nm. FIG. 9B corresponds to the case in which thickness of the organic functional layer was 10 nm and thickness of the organic light-emitting layer was 50 nm. Note that coordinates illustrated in FIGS. 8A, 8B, 9A, and 9B are (X, Y) coordinates.

As illustrated in FIG. 8A and FIG. 8B, a highest point 16A of the periphery of the organic functional layer 16, which had a flat shape, is (0.99, 0.01). Further, a highest point 17A of the periphery of the organic light-emitting layer 17 is (0.91, 0.09) in FIG. 8A and (0.94, 0.06) in FIG. 8B.

On the other hand, as illustrated in FIG. 9A and FIG. 9B, a pinning position 16P of the organic functional layer 16 is (0, 1) and an end point 16B where the organic functional layer 16 becomes flat is (1, 0.01). Further, a pinning position 17B of the organic light-emitting layer 17 is (0.2, 0.8), and an end point 17B where the organic light-emitting layer 17 becomes flat is (0.95, 0.09) in FIG. 9A and (0.98, 0.06) in FIG. 9B.

Note that in the simulations, relative luminance efficiency was estimated as a ratio of luminance efficiency of the organic light-emitting element including the organic light-emitting layer having a concave shape, as illustrated in FIGS. 9A and 9B, to luminance efficiency of the organic light-emitting element including the organic light-emitting layer having a flat shape, as illustrated in FIGS. 8A and 8B. Further, when compared to the organic light-emitting elements 910a and 910b including the organic functional layer having a flat shape, whether or not reduction in luminance efficiency was suppressed was evaluated for the organic light-emitting elements 10a and 10b including the organic functional layer having a concave shape. Note that here, suppression of reduction in luminance efficiency refers to a case in which relative luminance efficiency is 70% or greater.

### (Condition 1: Carrier Mobility of Organic Light-Emitting Layer)

The inventors performed simulations to verify how carrier mobility of the organic functional layer affects luminance efficiency. Physical properties of the organic light-emitting elements used in the simulations are as shown in table 1(a).

TABLE 1(a)

| | Thickness of | Carrier mobility | HOMO difference between |
|---|---|---|---|
| | organic light- | of organic | organic functional layer |
| | emitting layer | light-emitting | and organic light-emitting |
| | (nm) | layer (cm²/Vs) | layer (eV) |
| Case 1 | 80 | 2E−5 | 0.28 |
| Case 2 | 80 | 1E−7 | 0.38 |
| Case 3 | 50 | 2E−3 | 0.17 |

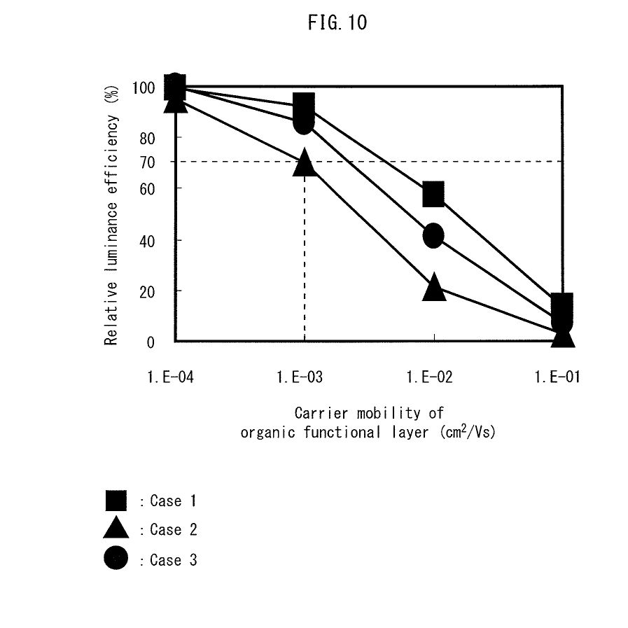

Results of simulations under these conditions are shown in table 2(a), and FIG. 10 is a graph plotted based on the results in table 2(a).

TABLE 2(a)

| | | | | | |
|---|---|---|---|---|---|
| Case 1 | Carrier mobility of organic | 1.0E−04 | 1.0E−03 | 1.0E−02 | 1.0E−01 |
| | functional layer (cm²/Vs) | | | | |
| | Relative luminance | 99.2 | 92.3 | 57.4 | 13.7 |
| | efficiency (%) | | | | |
| Case 2 | Carrier mobility of organic | 1.0E−04 | 1.0E−03 | 1.0E−02 | 1.0E−01 |
| | functional layer (cm²/Vs) | | | | |
| | Relative luminance | 95.2 | 70.2 | 21.5 | 3.0 |
| | efficiency (%) | | | | |
| Case 3 | Carrier mobility of organic | 1.0E−04 | 1.0E−03 | 1.0E−02 | 1.0E−01 |
| | functional layer (cm²/Vs) | | | | |
| | Relative luminance | 100.0 | 85.8 | 40.8 | 7.2 |
| | efficiency (%) | | | | |

FIG. 10 is a diagram illustrating how carrier mobility of the organic functional layer affects luminance efficiency. In FIG. 10, the horizontal axis indicates carrier mobility of the organic functional layer (cm²/Vs) and the vertical axis indicates relative luminance efficiency (%).

When luminance efficiency of the organic light-emitting elements 910a and 910b are used as a reference, relative luminance efficiency decreases as carrier mobility of the organic functional layer increases, as illustrated in FIG. 10. Examining these results in more detail, in all of cases 1-3, when carrier mobility of the organic functional layer was 1.0×10⁻³(cm²/Vs) and greater, reduction in relative luminance efficiency was significant, and when carrier mobility of the organic functional layer was in an inclusive range of 1.0×10⁻⁴(cm²/Vs) to 1.0×10⁻³(cm²/Vs), reduction in relative luminance efficiency was suppressed. Thus, a threshold of carrier mobility of the organic functional layer was set as 1.0×10⁻³(cm²/Vs). Note that for values of 1.0×10⁻⁴(cm²/Vs) or less for carrier mobility of the organic functional layer, the effect of current leakage on luminance efficiency may be considered to be further reduced. This is thought to be because for values of 1.0×10⁻⁴(cm²/Vs) or less for carrier mobility of the organic functional layer, luminance efficiency of the organic light-emitting elements 910a and 910b also decreases, reducing the difference in comparison with the organic light-emitting elements 10a and 10b.

Accordingly, as long as carrier mobility of the organic functional layer is 1.0×10⁻³(cm²/Vs) or less, excellent light-emitting properties are achieved.

### 3-3. Selection of Physical Properties of Organic Functional Layer and Organic Light-Emitting Layer

### (Overview)

The following describes physical properties of the organic functional layer and the organic light-emitting layer that more assuredly result in excellent light-emitting properties. Specifically, conditions 2-4 were determined through the same simulations as described under (3, 2), and are described below.

### (Condition 2: Carrier Mobility of Organic Light-Emitting Layer)

The inventors performed simulations to verify how carrier mobility of the organic light-emitting layer affects luminance efficiency. Further, an energy difference between the highest occupied molecular orbital (HOMO) of the organic functional layer and the organic light-emitting layer (hereafter, “HOMO difference between the organic functional layer and the organic light-emitting layer”) was simulated for the three combinations of values shown in table 1(b). Physical properties of the organic light-emitting elements used in the simulations were as shown in table 1(b). Note that HOMO difference between the organic functional layer and the organic light-emitting layer corresponds to energy barriers of each layer.

TABLE 1(b)

| | Thickness of | Carrier mobility | HOMO difference between |
|---|---|---|---|
| | organic light- | of organic | organic functional layer |
| | emitting layer | functional | and organic light-emitting |
| | (nm) | layer (cm^{2/}Vs) | layer (eV) |
| Case 1 | 80 | 1E−3 | 0.28 |
| Case 2 | 80 | 1E−3 | 0.38 |
| Case 3 | 50 | 1E−3 | 0.17 |

Carrier mobility of the organic functional layer shown in table 1(b) was 1.0×10⁻³(cm²/Vs), i.e. the threshold determined for suppressing reduction of luminance efficiency under condition 1.

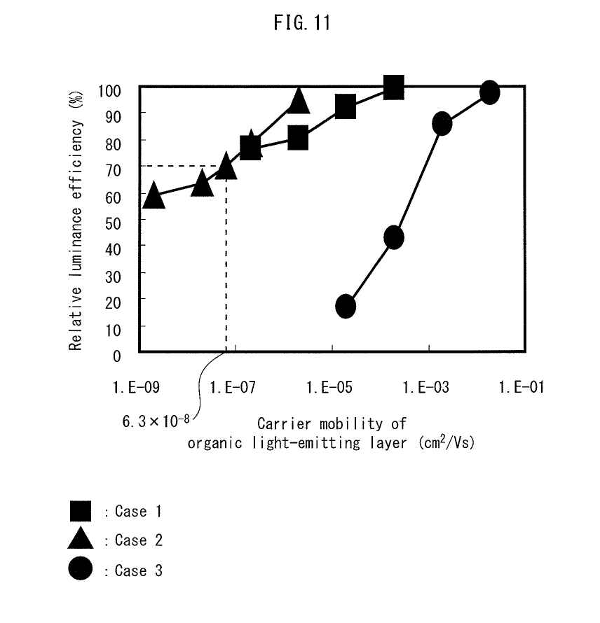

Results of simulations under these conditions are shown in table 2(b), and FIG. 11 is a graph plotted based on the results in table 2(b).

TABLE 2(b)

| | | | | | | |
|---|---|---|---|---|---|---|
| Case | Carrier mobility of | 2.0E−07 | 2.0E−06 | 2.0E−05 | 2.0E−04 | |
| 1 | organic functional | | | | | |
| | layer (cm²/Vs) | | | | | |
| | Relative luminance | 76.5 | 80.5 | 92.3 | 99.4 | |
| | efficiency (%) | | | | | |
| Case | Carrier mobility of | 2.0E−09 | 2.0E−08 | 6.32E−08 | 2.0E−07 | 2.0E−06 |
| 2 | organic functional | | | | | |
| | layer (cm²/Vs) | | | | | |
| | Relative luminance | 59.2 | 63.8 | 70.2 | 78.7 | 95.0 |
| | efficiency (%) | | | | | |
| Case | Carrier mobility of | 2.0E−05 | 2.0E−04 | 2.0E−03 | 2.0E−02 | |
| 3 | organic functional | | | | | |
| | layer (cm²/Vs) | | | | | |
| | Relative luminance | 16.6 | 42.9 | 85.8 | 97.5 | |
| | efficiency (%) | | | | | |

FIG. 11 is a diagram illustrating how carrier mobility of the organic light-emitting layer affects luminance efficiency. In FIG. 11, the horizontal axis indicates carrier mobility of the organic light-emitting layer (cm²/Vs) and the vertical axis indicates relative luminance efficiency (%).

In FIG. 11, for case 1 and case 2, when carrier mobility of the organic light-emitting layer was 6.3×10⁻⁸(cm²/Vs) or greater, reduction in luminance efficiency of the organic light-emitting elements 10a and 10b was suppressed within 30%. On the other hand, for case 3, while carrier mobility of the organic light-emitting layer of 6.3×10⁻⁸(cm²/Vs) or greater is a condition for suppressing reduction in luminance efficiency of the organic light-emitting elements 10a and 10b, it is insufficient to ensure suppressing reduction in luminance efficiency.

### (Condition 3: Energy Barrier of Organic Functional Layer and Organic Light-Emitting Layer)

The inventors performed simulations to verify how energy barriers of the organic functional layer and the organic light-emitting layer affect luminance efficiency. Physical properties (carrier mobility of the organic functional layer and carrier mobility of the organic light-emitting layer) of the organic light-emitting elements used in the simulations are as shown in table 1(c).

TABLE 1(c)

| | Thickness of | Carrier mobility | |
|---|---|---|---|
| | organic light- | of organic | Carrier mobility of |
| | emitting layer | functional | organic light-emitting |
| | (nm) | layer (cm²/Vs) | layer (cm²/Vs) |
| Case 1 | 80 | 1E−3 | 2E−5 |
| Case 2 | 80 | 1E−3 | 1E−7 |
| Case 3 | 50 | 1E−3 | 2E−3 |

Carrier mobility of the organic functional layer was 1.0×10⁻³(cm²/Vs), i.e. the threshold determined for suppressing reduction of luminance efficiency under condition 1.

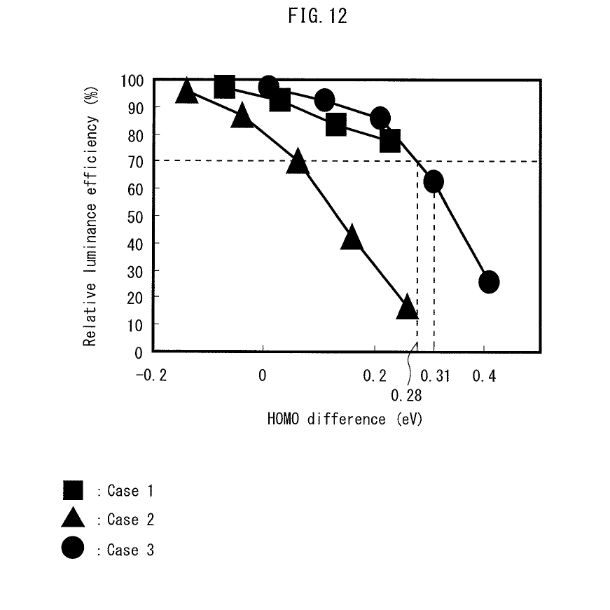

Results of simulations under these conditions are shown in table 2(c), and FIG. 12 is a graph plotted based on the results in table 2(c).

TABLE 2(c)

| | | | | | | |
|---|---|---|---|---|---|---|
| Case | HOMO difference between organic | −0.07 | 0.03 | 0.13 | 0.23 | |
| 1 | functional layer and organic | | | | | |
| | light-emitting layer (eV) | | | | | |
| | Relative luminance efficiency (%) | 97.0 | 92.3 | 83.1 | 77.6 | |
| Case | HOMO difference between organic | −0.14 | −0.04 | 0.06 | 0.16 | 0.26 |
| 2 | functional layer and organic | | | | | |
| | light-emitting layer (eV) | | | | | |
| | Relative luminance efficiency (%) | 95.7 | 86.7 | 70.27 | 42.17 | 16.67 |
| Case | HOMO difference between organic | 0.01 | 0.11 | 0.21 | 0.31 | 0.41 |
| 3 | functional layer and organic | | | | | |
| | light-emitting layer (eV) | | | | | |
| | Relative luminance efficiency (%) | 97.3 | 92.3 | 85.8 | 62.7 | 25.7 |

FIG. 12 is a diagram illustrating how HOMO difference between the organic functional layer and the organic light-emitting layer affects luminance efficiency. In FIG. 12, the horizontal axis indicates HOMO difference (eV) of the organic light-emitting layer and the organic functional layer, and the vertical axis indicates relative luminance efficiency (%).

In FIG. 12, for case 1 and case 3, when HOMO difference between the organic functional layer and the organic light-emitting layer was 028 eV or less, reduction in luminance efficiency of the organic light-emitting elements 10a and 10b was suppressed. On the other hand, for case 2, while HOMO difference between 0.28 eV or less is a condition for suppressing reduction in luminance efficiency, it is insufficient to ensure suppressing reduction in luminance efficiency.

### (Condition 4: Correlation Between HOMO Difference Between Organic Functional Layer and Organic Light-Emitting Layer and Carrier Mobility of Organic Light-Emitting Layer)

As mentioned above, carrier mobility of the organic light-emitting layer being 6.3×10⁻⁸(cm²/Vs) or greater (condition 2) and HOMO difference between the organic light-emitting layer and the organic functional layer being 0.28 eV or less (condition 3) are required conditions for all of cases 1-3, but are not necessarily sufficient to ensure suppression of reduction of luminance efficiency. Thus, the inventors performed simulations to examine correlation between HOMO difference (between the organic functional layer and the organic light-emitting layer) and carrier mobility (of the organic light-emitting layer), with respect to luminance efficiency. Physical properties of the organic light-emitting elements used in the simulations are as shown in table 1(d).

TABLE 1(d)

| | | | | | |
|---|---|---|---|---|---|
| Case 1 | Thickness of organic | 80 | 80 | 80 | 80 |
| | light-emitting layer (nm) | | | | |
| | Carrier mobility of organic | 2.0E−07 | 2.0E−06 | 7.7E−06 | 1.39E−05 |
| | light-emitting layer (cm²/Vs) | | | | |
| | HOMO difference between | 0.0483 | 0.0659 | 0.13 | 0.23 |
| | organic functional layer and | | | | |
| | organic light-emitting layer (eV) | | | | |
| Case 2 | Thickness of organic | 80 | 80 | 80 | 80 |
| | light-emitting layer (nm) | | | | |
| | Carrier mobility of organic | 2.0E−09 | 2.0E−08 | 2.0E−07 | 2.0E−06 |
| | light-emitting layer (cm²/Vs) | | | | |
| | HOMO difference between | 0.00974 | 0.0282 | 0.101 | 0.314 |
| | organic functional layer and | | | | |
| | organic light-emitting layer (eV) | | | | |
| Case 3 | Thickness of organic | 50 | 50 | 50 | 50 |
| | light-emitting layer (nm) | | | | |
| | Carrier mobility of organic | 2.0E−05 | 2.0E−04 | 2.0E−03 | 2.0E−02 |
| | light-emitting layer (cm²/Vs) | | | | |
| | HOMO difference between | 0.101 | 0.129 | 0.278 | 0.391 |
| | organic functional layer and | | | | |
| | organic light-emitting layer (eV) | | | | |

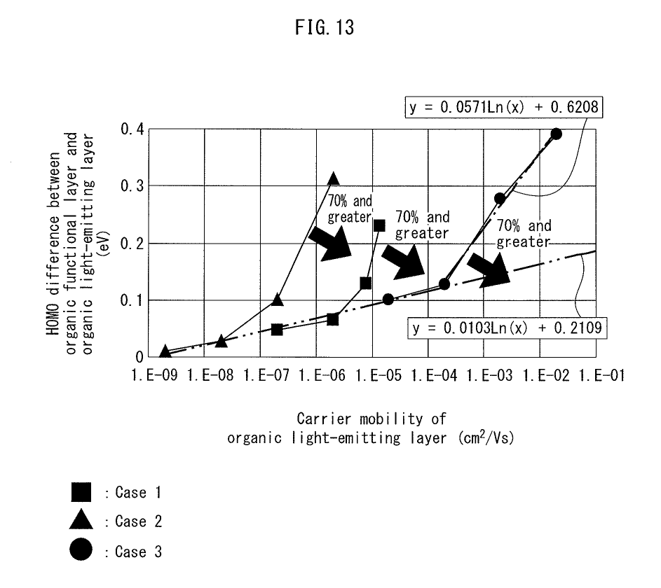

In cases 1-3, material of the organic light-emitting layer was different. Results of simulations under the above conditions are shown in FIG. 13.

FIG. 13 is a diagram illustrating correlation between HOMO difference between the organic functional layer and the organic light-emitting layer and carrier mobility of the organic light-emitting layer, with respect to luminance efficiency. In FIG. 13, the horizontal axis indicates carrier mobility of the organic light-emitting layer (cm²/Vs) and the vertical axis indicates HOMO difference between the organic light-emitting layer and the organic functional layer (eV). Further, in FIG. 13, contour lines show a ratio of luminance efficiency of the organic light-emitting elements 10a and 10b, which include the organic functional layer having a flat shape, to luminance efficiency of the organic light-emitting elements 910a and 910b, which include the organic functional layer having a concave shape. Thus, lines are plotted on the condition that relative luminance efficiency is 70%, and lines for case 1, case 2, and case 3 are superimposed on one graph. In this way, for cases 1-3, carrier mobility of the organic light-emitting layer and HOMO differences of the organic light-emitting layer and the organic functional layer that result in relative luminance efficiency of 70% are made clear.

Next, using FIG. 13, for cases 1-3, favorable ranges of relative luminance efficiency that are 70% or greater were examined.

When carrier mobility of the organic light-emitting layer is low, areas of few holes are less likely to occur at an interface between the organic functional layer and the organic light-emitting layer. Thus, holes are less likely to moves from the organic functional layer to the organic light-emitting layer. As a result, carrier injections properties from the organic functional layer to the organic light-emitting layer are degraded. Further, when HOMO differences of the organic light-emitting layer and the organic functional layer are large, carrier injection properties from the organic functional layer to the organic light-emitting layer are degraded. Thus, when carrier mobility of the organic light-emitting layer is low and HOMO difference between the organic light-emitting layer and the organic functional layer is high, leak current via the periphery of the organic functional layer flows more easily from the organic functional layer to the organic light-emitting layer. Such values are represented by the upper left region of FIG. 13. On the other hand, when carrier mobility of the organic light-emitting layer is high and HOMO difference between the organic light-emitting layer and the organic functional layer is low, carrier injection properties from the organic functional layer to the organic light-emitting layer improve. Thus, leak current via the periphery of the organic functional layer is less likely to occur and relative luminance efficiency increases. Thus, relative luminance efficiency increases in regions further right and down in FIG. 13.

Here, among the plotted lines of cases 1-3, the plotted line of case 3 represents the case having the lowest luminance efficiency. For example, when carrier mobility of the organic light-emitting layer is 1.39×10⁻⁵(cm²/Vs) and HOMO difference between the organic light-emitting layer and the organic functional layer is 0.23 eV, case 1 has relative luminance efficiency of 70% but case 3 has relative luminance efficiency less than 70%. In this way, as long as ranges are used that result in relative luminance efficiency of 70% or greater for all plotted lines of cases 1-3, suppression of reduction of luminance efficiency can be achieved for organic light-emitting elements including organic light-emitting layers composed of any material. The following examines such ranges.

In an inclusive range of carrier mobility of the organic light-emitting layer from 1.0×10⁻⁹(cm²/Vs) to 1.0×10⁻⁴(cm²/Vs), for all plotted lines of cases 1-3, relative luminance efficiency is 70% or greater when carrier mobility of the organic light-emitting layer and HOMO difference between the organic light-emitting layer and the organic functional layer satisfy Math 1.

Y≦0.0103Ln(X)+0.2109(1.0×10⁻⁹≦X≦1.0×10⁻⁴) Math 1

The region below the two-dot chain line in FIG. 13 corresponds to Math 1.

On the other hand, in an inclusive range of carrier mobility of the organic light-emitting layer from 1.0×10⁻⁴(cm²/Vs) to 1.0×10⁻¹(cm²/Vs), for all plotted lines of cases 1-3, relative luminance efficiency is 70% or greater when carrier mobility of the organic light-emitting layer and HOMO difference between the organic light-emitting layer and the organic functional layer satisfy Math 2.

Y≦0.0571Ln(X)+0.6208(1.0×10⁻⁴≦X≦1.0×10⁻¹) Math 2

The region below the one-dot chain line in FIG. 13 corresponds to Math 2.

However, due to material development related to the organic light-emitting layer, some changes in carrier mobility of the organic light-emitting layer and HOMO difference between the organic functional layer and the organic light-emitting layer when relative luminance efficiency is 70% may be considered. Thus, in view of past simulations in which materials changed, the inventors estimated a change of approximately 5% with respect to case 1, case 2, and case 3. Thus, it can be said that carrier mobility of the organic light-emitting layer and HOMO difference between the organic light-emitting layer and the organic functional layer will be close to that of case 1, case 2, and case 3 when relative luminance efficiency is 70% for any configuration of organic light-emitting element.

Accordingly, in all of cases 1-3, a region in which reduction of luminance efficiency is suppressed for the organic light-emitting elements 10a and 10b, which include the organic functional layer having a concave shape, is clearly defined by ranges that satisfy Math 1 and Math 2.

As long as the organic functional layer and the organic light-emitting layer that satisfy conditions 2-4 are used, further improvements in luminance efficiency can be achieved.

### (Specific Example of Organic Functional Layer and Organic Light-Emitting Layer)

By selecting the organic functional layer and the organic light-emitting layer having physical properties that satisfy conditions 1-4, the organic light-emitting element having further improved luminance efficiency can be achieved. Specifically, poly(vinylcarbazole) (PVK) can be used as the organic functional layer and fluorene (F8) material can be used as the organic light-emitting layer. Carrier mobility of PVK is 1.0×10⁻⁵(cm²/Vs) to 1.0×10⁻⁶(cm²/Vs) (reference document: Japanese Patent Application Publication H11-144525), which satisfies condition 1. Carrier mobility of F8 material is 5×10⁻³(cm²/Vs) (reference document: Japanese Patent Application Publication 2008-282957), which satisfies condition 2. Further, it is generally known that HOMO values of PVK are around 5.6 eV to 5.9 eV (reference documents: Japanese Patent Application Publication 2001-284060, and J. Kido, H. Shionoya, and K. Nagai, Appl. Phys. Lett. 67 2881 (1995)), and HOMO values of F8 materials are around 5.8 eV (reference document: Adv. Mater. 2004, 16, No. 6, March 18). Thus, by using poly(vinylcarbazole) (PVK) as the organic functional layer and fluorene (F8) material as the organic light-emitting layer, HOMO difference between the organic light-emitting layer and the organic functional layer is 0.2 eV or less, satisfying condition 3 and condition 4. Accordingly, by using the materials described above, the organic functional layer and the organic light-emitting layer satisfy conditions 1-4.

### <Modifications>

The preferred embodiment is described above, but the following modifications may be considered.

### (1) Shape of Organic Functional Layer, Organic Light-Emitting Layer, and Bank Layer

In the above embodiment, the organic functional layer is present between all of the periphery of the organic light-emitting layer and the inclined surface of the bank layer. However, the present invention is not limited in this way, and as long as the organic functional layer is present between at least a portion of the periphery of the organic light-emitting layer and the inclined surface of the bank layer, advantageous effects of the invention may be achieved. Note that “at least a portion of the periphery” here means a portion excluding an error range of the periphery.

### (2) Organic Light-Emitting Display Device

In the above embodiment, a color of emitted light of the organic light-emitting layer in the organic light-emitting display device is not mentioned. However, without being limited to monochrome display, the present invention may be applied to a full-color display organic light-emitting display device. In a full-color display organic light-emitting display device, a single organic light-emitting element corresponds to a sub-pixel of an RGB pixel. Adjacent sub-pixels combine to form a single pixel, and such a pixel is arranged in a matrix to form an image display region.

Further, in the above embodiment, a top-emission type of organic light-emitting display device is described as an example, but the same implementation applies when forming an organic light-emitting layer in a bottom-emission type of organic light-emitting display device.

### (3) Method of Producing Organic Functional Layer and Organic Light-Emitting Layer

In the above embodiment, the organic functional layer having a concave shape is formed by adjusting density of ink that is material for the organic functional layer and determining the method of drying the ink. However, the present invention is not limited in this way. For example, by reducing liquid repellency of the inclined surface of the bank layer facing the opening, i.e. increasing wettability, ink that is material for the organic functional layer heaps into a convex shape and a high pinning position of the organic functional layer may be achieved. Specifically, after forming the bank layer, wettability of the inclined surface of the bank layer facing the opening may be increased by exposure to ultraviolet (UV) rays.

Further, in the above embodiment, the organic functional layer and the organic light-emitting layer are produced by application using an inkjet method. However, the present invention is not limited in this way. Ink for the organic functional layer and the organic light-emitting layer may be dropped or applied by known methods such as spin-coating, gravure printing, dispensing, nozzle coating, intaglio printing, relief printing, etc.

### (4) Material of Organic Functional Layer and Organic Light-Emitting Layer

In the above embodiment, PVK is used as the organic functional layer and F8 material is used as the organic light-emitting layer. However, the present invention is not limited in this way. As long as an organic functional layer having a concave shape may be formed and carrier mobility of the organic functional layer is 1.0×10⁻³(cm²/Vs) or less, other materials may be used for the organic functional layer and the organic light-emitting layer.

### (5) Functions of Organic Functional Layer

In the above embodiment, the organic functional layer has a hole transport function. However, the present invention is not limited in this way. The organic functional layer may have a carrier transport function, a carrier injection function, or a function of blocking carrier transport. Here, “carrier” is not limited to holes, and may mean electrons.

### (6) Other

Although not illustrated in the above embodiment, metal auxiliary wiring may be provided on the substrate. When voltage is applied from the periphery of the cathode, voltage variance in the periphery and central portion of the cathode may be suppressed by electrical connection between the auxiliary wiring and the cathode.

### INDUSTRIAL APPLICABILITY

The organic light-emitting element pertaining to an aspect of the present invention and the organic light-emitting display device using the organic light-emitting element may be widely used in production of organic light-emitting elements by wet processes and/or drip processes. Further, the organic light-emitting element pertaining to an aspect of the present invention may be widely used in the general fields of passive matrix and active matrix types of organic display devices and organic light-emitting devices, for example.

### REFERENCE SIGNS LIST

10 organic light-emitting display device
11 substrate
12 anode
13 ITO layer
14 hole injection layer
15 bank layer
15a opening
15b inclined surface
16 hole transport layer
17 organic light-emitting layer
17a periphery
18 electron injection layer
19 cathode
20 sealing layer

1. An organic light-emitting element comprising:
a substrate;
a first electrode on the substrate;
a bank layer on or above the substrate, the bank layer having an opening above the first electrode;
an organic functional layer in the opening, the organic functional layer containing organic material;
an organic light-emitting layer on the organic functional layer, the organic light-emitting layer containing organic light-emitting material; and
a second electrode above the organic light-emitting layer, wherein
a portion of the organic functional layer is located between at least a portion of a periphery of the organic light-emitting layer and a side surface of the bank layer facing the opening, and
carrier mobility of the organic functional layer is 1.0×10⁻³ cm²/Vs or less.

2. The organic light-emitting element of claim 1, wherein
a difference between HOMO of the organic functional layer and HOMO of the organic light-emitting layer is 0.28 eV or less,
carrier mobility of the organic light-emitting layer is 6.3×10⁻⁸ cm²/Vs or greater,
when X satisfies 1.0×10⁻⁹≦X≦1.0×10⁻⁴
Y≦0.0103Ln(X)+0.2109
and when X satisfies 1.0×10⁻⁴≦X≦1.0×10⁻¹
Y≦0.0571Ln(X)+0.6208
where X is the carrier mobility of the organic light-emitting layer and Y is the difference between HOMO of the organic functional layer and HOMO of the organic light-emitting layer.

3. The organic light-emitting element of claim 1, wherein
the side surface of the bank layer facing the opening is inclined with respect to a surface of the substrate,
periphery of the organic functional layer is located on the side surface of the bank layer facing the opening, and
the periphery of the organic light-emitting layer is positioned further towards a center of the opening than the periphery of the organic functional layer.

4. The organic light-emitting element of claim 1, further comprising:
an intermediate layer between the organic light-emitting layer and the second electrode.

5. The organic light-emitting element of claim 1, further comprising:
a carrier injection layer between the first electrode and the organic functional layer.

6. The organic light-emitting element of claim 5, wherein
a portion of the carrier injection layer is located in regions other than between the first electrode and the organic functional layer, and
the portion of the carrier injection layer in the regions other than between the first electrode and the organic functional layer is located between the substrate and the bank layer.

7. The organic light-emitting element of claim 1, further comprising:
metal auxiliary wiring on the substrate, wherein
the second electrode and the auxiliary wiring are connected.

8. A method of producing an organic light-emitting element, comprising:
preparing a substrate having a plurality of first electrodes thereon;
forming a bank layer on or above the substrate, the bank layer having openings, each opening being above a respective one of the first electrodes;
forming organic functional layers in the openings by applying then drying a solution containing organic material, carrier mobility of the organic functional layers being 1.0×10⁻³ cm²/Vs or less;
forming organic light-emitting layers on the organic functional layers by applying then drying a solution containing organic light-emitting material; and
forming a second electrode above the organic light-emitting layers, wherein
a portion of each organic functional layer is located between at least a portion of a periphery of a respective one of the organic light-emitting layers and a corresponding side surface of the bank layer facing a respective one of the openings.
